(19) United States
(12) Patent Application Publication
(10) Pub. No.: US 2025/0349679 A1
(43) Pub. Date: Nov. 13, 2025

(54) SEMICONDUCTOR DEVICE CONFIGURED WITH IMMERSION COOLING AND REDUCED PARASITICS

(71) Applicant: Analog Power Conversion LLC, Bend, OR (US)

(72) Inventors: Wang-Chang A. GU, Bend, OR (US); Dumitru G SDRULLA, Bend, OR (US)

(21) Appl. No.: 18/658,627

(22) Filed: May 8, 2024

(51) Int. Cl. H01L 23/495; H01L 23/31

(52) U.S. Cl. CPC H01L 23/49568; H01L 23/3107; H01L 23/4951

(57) ABSTRACT

A semiconductor device including one or more semiconductor dies is configured for cooling by immersion in a coolant contained in a chamber. The semiconductor device provides efficient dissipation of heat from the one or more semiconductor dies to the coolant while providing a low impedance or controlled-impudence electrical interconnect between the one or more semiconductor dies and circuitry outside the chamber. The semiconductor device may be configured in the shape of a fin. The semiconductor device may have a plurality of co-planar leads that pass through a wall of the chamber.

### BACKGROUND

A semiconductor device may generate large amounts of heat in a very small volume. Even semiconductor devices not designed to control high amounts of power, such as processors, may dissipate in excess of 100 watts per square centimeter. Accordingly, in order to keep the temperature of the semiconductor device in a safe range, effective cooling is required.

Historically, semiconductor die has been cooled by thermal conduction through a substrate that the semiconductor die was attached to. The substrate could then be attached to a cold plate.

However, the heat removal capacity of such a cooling apparatus is generally limited, both by the intrinsic geometry of the apparatus and by the need to use materials with specific mechanical or electrical characteristics (such as dielectrics or polymers) where the materials have relatively poor thermal conductivity.

In addition, the geometries and materials used in such substrate-based cooling solutions often introduces parasitic capacitances, parasitic inductances, or both (collectively called parasitics) that may degrade the performance of the semiconductor device.

Accordingly, a need exists for a cooling system that can efficiently remove a large amount of heat from a semiconductor device without introducing performance-degrading parasitics.

### SUMMARY OF THE INVENTION

Embodiments relate to a semiconductor device configured for immersion cooling in a chamber and comprising a low-impendence or controlled-impedance electrical interface for electrical communication with circuits outside the chamber.

In an embodiment, a semiconductor device comprising a first lead comprising a planar stripline, a second lead comprising a planar stripline; and a first semiconductor die mounted on the first lead. The first semiconductor die comprises a bottom pad disposed on a first side of the first semiconductor die and a first top pad disposed on a second side of the first semiconductor die. The bottom pad is electrically coupled to the first lead, and the first top pad disposed is electrically coupled to the second lead. The shape of the semiconductor device corresponds to a fin, and the semiconductor device is configured for immersion cooling.

In embodiments, the first and second leads comprise a low impedance or controlled-impendence interconnect between the first semiconductor die and circuitry external to the semiconductor device.

In embodiments, the first lead is soldered or brazed to the bottom pad, and the second lead is soldered or brazed to the first top pad.

### BRIEF DESCRIPTION OF THE DRAWINGS

FIG. 1 illustrates an immersion-based cooling system according to an embodiment.

FIGS. 2A, 2B, and 2C are top plan, side, and bottom plan views, respectively, of a semiconductor device according to an embodiment.

FIGS. 3A, 3B, and 3C are top plan, side, and bottom plan views, respectively, of a semiconductor device according to another embodiment.

FIGS. 4A, 4B, and 4C are top plan, side, and bottom plan views, respectively, of a semiconductor device according to another embodiment.

FIGS. 5A, 5B, 5C, and 5D are top plan, side edge, bottom plan, and bottom edge views, respectively, of a semiconductor device according to another embodiment.

FIG. 6 illustrates a semiconductor device according to another embodiment.

FIG. 7 illustrates a configuration of a semiconductor device according to an embodiment in a chamber of an immersion cooling system.

FIG. 8 illustrates a configuration of semiconductor devices according to an embodiment in a chamber of an immersion cooling system.

FIG. 9 illustrates another configuration of semiconductor devices according to an embodiment in a chamber of an immersion cooling system.

FIG. 10 illustrates another configuration of semiconductor devices according to an embodiment in a chamber of an immersion cooling system.

FIG. 11 illustrates another configuration of semiconductor devices according to an embodiment in a chamber of an immersion cooling system.

### DETAILED DESCRIPTION

Embodiments of the present application relate to cooling of electronic devices, and in particular to a cooling a semiconductor device by immersion in a fluid-filled chamber while providing a low-impendence or controlled-impedance electrical interface between the semiconductor device and electronic circuits outside of the fluid-filled chamber.

Although embodiments presented herein may be described with respect to three-terminal semiconductor devices such as power semiconductors, embodiments are not limited thereto, and in other embodiments, the invention may be applied to computer processing units (CPUs), graphics processing units (GPUs), machine learning processors, and the like.

A detailed description of embodiments is provided below along with accompanying figures. The scope of this disclosure is limited only by the claims and encompasses numerous alternatives, modifications and equivalents. Although steps of various processes are presented in a given order, embodiments are not necessarily limited to being performed in the listed order. In some embodiments, certain operations may be performed simultaneously, in an order other than the described order, or not performed at all.

Numerous specific details are set forth in the following description. These details are provided to promote a thorough understanding of the scope of this disclosure by way of specific examples, and embodiments may be practiced according to the claims without some of these specific details. Accordingly, the specific embodiments of this disclosure are illustrative, and are not intended to be exclusive or limiting. For the purpose of clarity, technical material that is known in the technical fields related to this disclosure has not been described in detail so that the disclosure is not unnecessarily obscured. Furthermore, features in drawings may not all be drawn to the same scale, may be exaggerated in one or more dimensions, or both in the interest of clarity.

A semiconductor device may be cooled using immersion cooling. In immersion cooling, the semiconductor device is sealed inside a chamber containing a fluid coolant such that the semiconductor device is immersed in the coolant. Electrical connections to the semiconductor device may be made using leads extending from the semiconductor device out through the walls of the chamber.

The coolant operates to transfer the heat generated by the semiconductor device to a thermal sink that is better able to dispute the heat in the operational environment than the semiconductor device would have. The thermal sink may include the walls of the chamber, a heat sink composed of a material with a high thermal conductivity and having a high surface area, a radiator having fins coupled to pipes through which the coolant flows, or other such thermal energy dissipation apparatus as are known in the arts, or combinations thereof.

In some immersion cooling systems, the coolant may be circulated by a pump. In other immersion cooling systems, the coolant may be circulated by convection as a result of the heat transferred from the semiconductor device. In other immersion cooling systems, the coolant may be circulated by a phase-changes such as boiling and condensation.

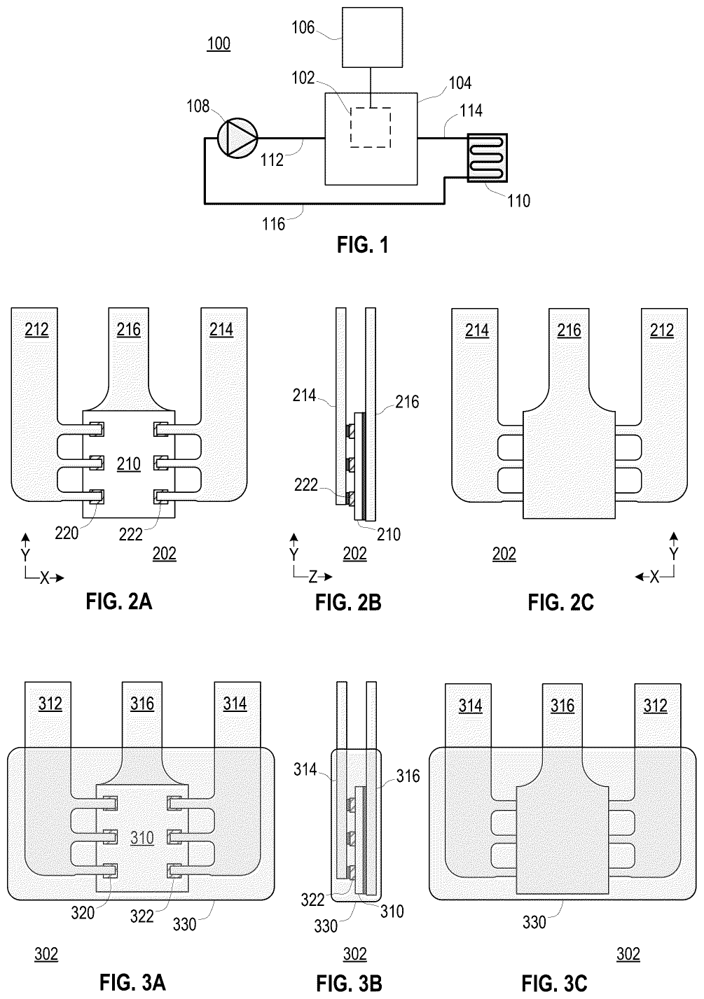

FIG. 1 illustrates an immersion-based cooling system 100 according to an embodiment. The cooling system includes a semiconductor device 102, a chamber 104, external circuitry 106, a pump 108, and a radiator 110.

The external circuitry 106 is electrically coupled to the semiconductor device 102. The external circuitry 106 may include circuits that provide power to semiconductor device 102, circuits that control the semiconductor device 102, circuits that are controlled by the semiconductor device 102, circuits that receive power from the semiconductor device 102, or combinations thereof.

Coolant is circulated by the pump 108 to the chamber 106 through a supply line 112, flows from the chamber 106 to the radiator 110 through an output line 114, and returns to the pump 108 from the radiator 110 through a return line 116. The coolant removes heat from the semiconductor device 102 and transfers it to the radiator 110. The radiator 110 transfers the heat to the local environment.

The cooling system 100 is illustrative and not limiting. Other cooling systems incorporating embodiments may include, for example, Peltier device, heat pipes, heat exchangers, heat sinks, fans, heat pumps, refrigeration systems, and other such devices as known in the related arts.

The coolant may be deionized water, alone or in combination with additives, such as an inhibited glycol and water solution. As an alternative, the coolant may be an inert electrically-insulating fluid such as a fluorocarbon (e.g., Fluorinert™ or Novec™) or polyalphaolefin (PAO).

FIGS. 2A, 2B, and 2C are top plan, side, and bottom plan views, respectively, of a semiconductor device 202 according to an embodiment. The semiconductor device 202 may correspond to the semiconductor device 102 of FIG. 1. Note that in FIG. 2B, the thicknesses of the features shown therein are exaggerated to in the interest of clarity.

The semiconductor device 202 comprises a semiconductor die 210 having one or more electronic devices disposed therein and having one or more left pads 220 and one or more right pads 222 for electrically coupling that circuitry to those electronic devices. Furthermore, the bottom surface of the semiconductor device 202 is configured to operate as a bottom pad (not shown) for electrically coupling those electronic devices to external circuits.

In illustrative examples wherein the electronic devices include three-terminal device such as a Vertical Metal-Oxide-Semiconductor Field Effect Transistor (V-MOSFET) or Vertical Insulated Gate Bipolar Transistor (V-IGBT), the one or more left pads 220 may providing electrical coupling to a control gate of the three-terminal device, the one or more right pads 222 may providing electrical coupling to a first conduction terminal (e.g., a source or collector) of the three-terminal device, and the bottom pad may provide electrical coupling to a second conduction terminal (e.g. a drain or emitter) of the three-terminal device. However, embodiments are not limited to this example.

The semiconductor device 202 further comprises first, second, and third leads 212, 214, and 216, each composed of a conductive material such as, for example, an aluminum alloy, a copper alloy, or the like. In embodiments, the first, second, and third leads 212, 214, and 216 are comprised of planar transmission lines, that is, flat ribbon-shaped conductors. Together the semiconductor die 210 and the first, second, and third leads 212, 214, and 216 form a “fin,” that is, having a thickness in a Z direction that is less than a small fraction (such as one-third, one-quarter, or less) of each of the its length in an X direction and its height in a Y direction.

The bottom of the semiconductor die 210 is disposed on the third lead 216 in a manner that electrically couples the third lead 216 to the bottom pad of the semiconductor die 210. For example, the bottom of the semiconductor die 210 may be soldered or brazed to the third lead 216; in an embodiment using soldering, the dark feature disposed between the semiconductor die 210 and the third lead 216 in FIG. 2B may correspond to solder.

The first lead 212 is coupled to the one or more left pads 220 of the semiconductor die 210 in a manner that electrically couples the first lead 212 to the one or more left pads 220. For example, the first lead 212 may be soldered or brazed to the one or more left pads 220.

The second lead 214 is coupled to the one or more right pads 222 of the semiconductor die 210 in a manner that electrically couples the second lead 214 to the one or more right pads 222. For example, the second lead 214 may be soldered or brazed to the one or more right pads 222; in an embodiment using soldering, the dark feature disposed between the one or more right pads 222 and the second lead 214 in FIG. 2B may correspond to solder.

In embodiments, the first, second, and third leads 212, 214, and 216 are metal.

In embodiments, the first, second, and third leads 212, 214, and 216 are precision-manufactured, such as by precision machining, to mate with the pads of the semiconductor die 210.

In the illustrated configuration, the top surface of the semiconductor die 210 and the bottom surface of the third lead 216 together provide a primary heat dissipation path from the device(s) on the semiconductor die 210 to a coolant in which the semiconductor device 202 is at least partially submerged. Because of the primary heat dissipation path's short length and large surface area, the heat dissipation path has high thermal conductivity.

Furthermore, the one or more left pads 220 and the first lead 212 provide a first secondary heat dissipation path from the device(s) on the semiconductor die 210 to the coolant, and the one or more right pads 220 and the second lead 214 provide a second secondary heat dissipation path from the device(s) on the semiconductor die 210 to the coolant. While the thermal conductivity of each of the first and second heat dissipation paths may be less than that of the primary heat dissipation path, the first and second heat dissipation paths may still provide substantial additional heat conduction from the device(s) on the semiconductor die 210 to the coolant.

Furthermore, the configuration of the first, second, and third leads 212, 214, and 216, shown in FIG. 2 results in low parasitics, such as in low parasitic capacitances between first and third leads 212 and 216 and between second and third leads 214 and 216. As a result, the first, second, and third leads 212, 214, and 216 may be more readily configured as a low impedance interconnect or as an impedance-controlled interconnect than alternative in the related arts.

The semiconductor device 202 may be appropriate for use with coolants that are chemically inert with respect to the semiconductor device 202 and electrically non-conductive, such as, for example, Fluorinert™. However, for use with other coolants, such as water-based coolant, protection of the one or more of the components of the semiconductor device 202 may be necessary.

FIGS. 3A, 3B, and 3C are top plan, side, and bottom plan views, respectively, of a semiconductor device 302 according to another embodiment. Note that in FIG. 3B, the thicknesses of the features shown therein are exaggerated to in the interest of clarity.

The semiconductor device 302 comprises a semiconductor die 310 having one or more left pads 320, one or more right pads 322, and a bottom pad (not shown), and first, second, and third leads 312, 314, and 316, each of which is configured as described for the corresponding features of semiconductor device 202 of FIGS. 2A-2C. In addition, the semiconductor device 302 comprises an encapsulation 330.

The encapsulation 330 encases the semiconductor die 310, the one or more left pads 320, the one or more right pads 322, and the bottom pad (not shown), and in the illustrated embodiments portions of each of the first, second, and third leads 312, 314, and 316. The encapsulation 330 may comprise an electrically non-conductive material.

The encapsulation 330 operates to protect the semiconductor die 310 (and in some embodiments, the first, second, and third leads 312, 314, and 316) from the coolant. The encapsulant 330 may also improve the mechanical properties of the semiconductor device 302, making it less likely to be damaged when handled or when subjected to stress or strain. The encapsulation may be any of suitable materials known in the related arts.

In embodiments, a thickness of the encapsulation 330 over the semiconductor die 310 and the first, second, and third leads 312, 314, and 316 is thin so that the encapsulation 330 does not substantially interfere with the transfer of heat from the semiconductor die 310 to the coolant. For example, in an embodiment, a thickness of the encapsulation 330 over the semiconductor die 310, the third lead 315, or both may be 5 microns or less.

In embodiments, the encapsulation 330 may be a material with low electrical conductivity but high thermal conductivity, such as a filled epoxy encapsulant, a filled silicone encapsulant, a filled polymer encapsulant, or other suitable material know in the related arts.

Because of the protection provided by the encapsulation 330, the semiconductor device 302 may be immersed in coolants (for example, water-based coolants) that would damage the semiconductor device 202 of FIG. 2.

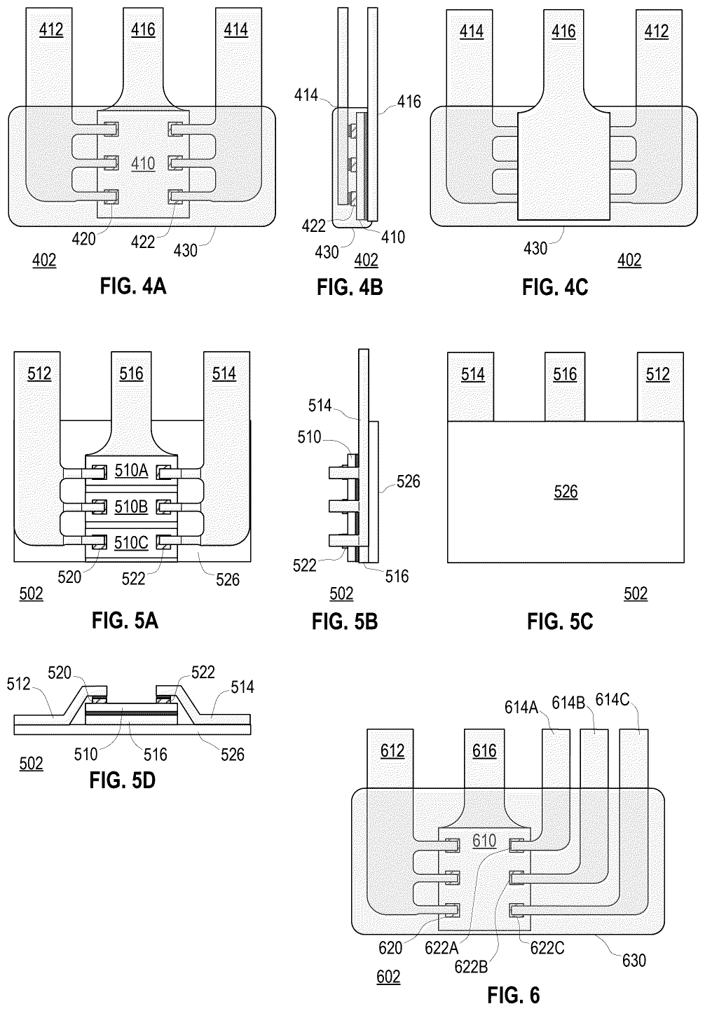

FIGS. 4A, 4B, and 4C are top plan, side, and bottom plan views, respectively, of a semiconductor device 402 according to another embodiment. Note that in FIG. 4B, the thicknesses of the features shown therein are exaggerated to in the interest of clarity.

The semiconductor device 402 comprises a semiconductor die 410 having one or more left pads 420, one or more right pads 422, and a bottom pad (not shown), and first, second, and third leads 412, 414, and 416, each of which is configured as described for the corresponding features of semiconductor device 302 of FIGS. 3A-3C.

Like the semiconductor device 302 of FIGS. 3A-3C, the semiconductor device 402 comprises an encapsulation 430. However, the semiconductor device 402 differs from the semiconductor device 302 in that the encapsulation 430 encloses the semiconductor die 410, the one or more left pads 420, the one or more right pads 422, and portions of the first and second leads 412 and 414, but only encloses portions of the top side of the third lead 416, so that a bottom side of the third lead 416 is in contact with the coolant.

Accordingly, the bottom of the semiconductor die 410 is protected from the coolant by the third lead 416 rather than by the encapsulant 430.

The semiconductor device 402 is suitable for use with coolants that do not damage the materials comprising the third lead 416, and by eliminating the layer of encapsulant over the bottom of the third lead 416 improves the thermal conductivity of the heat dissipation path.

FIGS. 5A, 5B, 5C, and 5D are top plan, side edge, bottom plan, and bottom edge views, respectively, of a semiconductor device 502 according to another embodiment. Note that in FIGS. 5B and 5D, the thicknesses of the features shown therein are exaggerated to in the interest of clarity

The semiconductor device 502 comprises first, second, and third leads 512, 514, and 516, each of which is generally configured as described for the corresponding features of semiconductor device 202 of FIGS. 2A-2C.

However, unlike the semiconductor device 202, the semiconductor device 502 comprises first, second, and third semiconductor dies 510A, 510B, and 510C disposed on the third lead 516 and each corresponding to the semiconductor die 210 of FIG. 2.

In addition, the semiconductor device 502 comprises a substrate 526 upon which the first, second, and third leads 512, 514, and 516 are mounted. The substrate 526 provides improvement to the mechanical properties of the semiconductor to the semiconductor device 502 when the semiconductor dies of the semiconductor device 502 do not need to be protected from the coolant.

Although the semiconductor device 502 comprising multiple semiconductor dies is shown in FIG. 5 combined with the substrate 526, embodiments are not limited thereto, and in embodiments, the semiconductor devices of FIGS. 2A to 2C, 3A to 3C, and 4A to 4C may also include a plurality of semiconductor dies disposed on the third lead of the semiconductor devices.

FIG. 6 illustrates a semiconductor device 602 according to another embodiment.

The semiconductor device 602 comprises a semiconductor die 610 having one or more left pads 620, first, second, and third right pads 622A, 622B, and 622C, and a bottom pad (not shown), first, second, third, fourth, and fifth leads 312, 314, 316A, 316B, and 316C, and an encapsulant 630, each of which is configured as described for the similarly-named feature of semiconductor device 302 of FIG. 3A.

The semiconductor device 602 differs from the semiconductor device 302 of FIG. 3A in that the semiconductor device 302 is a three-terminal device while the semiconductor device 602 is a five-terminal device. Accordingly, FIG. 6 demonstrates that embodiments are not limited to three terminal devices, but may instead have any number of terminals.

In some embodiments, such as shown in FIGS. 5A to 5C, the leads of the semiconductor device may be co-planar at the point at which the leads (as shown below) penetrate a wall of a chamber of cooling system. In other embodiments, as shown in FIGS. 2A to 2C, 3A to 3C, and 4A to 4C, leads electrically coupled to a pad on a first surface of a semiconductor die of the semiconductor device may lie in a first plane when penetrating the wall, and leads electrically coupled to a pad on a second surface of the semiconductor die of the semiconductor device may lie in a second plane when penetrating the wall.

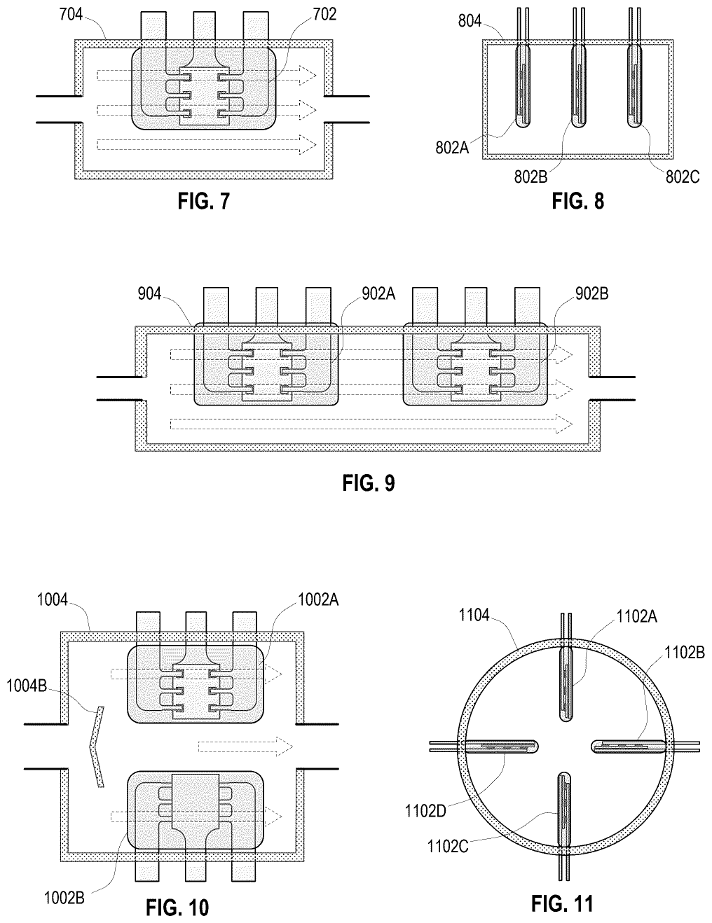

Due to the fin-like physical configuration of semiconductor devices according to embodiments, one or more embodiments may be configured in a chamber of an immersion cooling system in a variety of ways, as illustrated in FIGS. 7-11, below.

In FIGS. 7, 9, and 10, dashed block arrows indicate a direction of coolant flow in the chamber. In FIGS. 8 and 10, the fluid is flowing perpendicular to the plane of the illustration.

FIG. 7 illustrates a configuration of a semiconductor device 702 according to an embodiment in a chamber 704 of an immersion cooling system. The semiconductor device may be any of the previously disclosed embodiments.

The semiconductor device 702 is mounted with its lead passing through the wall of the chamber 704. In cases where the wall of the chamber 702 is electrically conductive, an insulating seal such as is known to the art may be used to electrically isolate the leads from the wall of the chamber. Otherwise, any suitable means of sealing the wall of the chamber around the leads known in the related arts may be used.

The semiconductor device 702 is shown mounted with its encapsulation flush to the wall of the chamber 704, so that the leads of the semiconductor device 702 are not exposed to the coolant.

FIG. 8 illustrates a configuration of first, second, and third semiconductor devices 802A, 802B, and 802C according to an embodiment in a chamber 804 of an immersion cooling system. FIG. 8 shows a cross-section perpendicular to a direction of the coolant flow, so that the coolant flow is in a direction out of the figure.

The first, second, and third semiconductor devices 802A, 802B, and 802C are disposed in parallel to each other relative to the flow of the coolant. Each is mounted as described for the semiconductor device 702 of FIG. 7.

FIG. 9 illustrates a configuration of first and second semiconductor devices 902A and 902B according to an embodiment in a chamber 904 of an immersion cooling system.

The first and second semiconductor devices 902A and 902B are mounted in series to each other relative to the flow of the coolant.

The mounting of the first and second semiconductor devices 902A and 902B differs from the mounting of the semiconductor device 702 of FIG. 7 in that in FIG. 9, the encapsulant of the second semiconductor devices accompanies the leads in penetrating the wall of the chamber 904, so that a single opening in the wall is used for each of the first and second semiconductor devices 902A and 902B, rather than the three openings used for the semiconductor device 702. This may make it easier to seal the openings around each of the first and second semiconductor devices 902A and 902B, and may better protect the leads from the coolant.

FIG. 10 illustrates another configuration of first and second semiconductor devices 1002A and 1002B according to an embodiment in a chamber 1004 of an immersion cooling system.

The first and second semiconductor devices 1002A and 1002B are mounted on opposite walls of the chamber 1004. Furthermore, the chamber 1004 includes a baffle 1004B that operates to ensure that sufficient coolant flow passes over each of the first and second semiconductor devices 1002A and 1002B.

The mounting of the semiconductor devices 1002A and 1002B differs from the mounting of the semiconductor device 702 of FIG. 7 in that portions of the leads of the semiconductor devices 1002A and 1002B are exposed to the coolant, which may improve heat transfer to the coolant for coolants that are not harmful to the leads.

FIG. 11 illustrates a configuration of first, second, third, and fourth semiconductor devices 1102A, 1102B, 1102C, and 1102D according to an embodiment in a chamber 1104 of an immersion cooling system. FIG. 11 shows a cross-section perpendicular to direction of the coolant flow, so that the coolant flow is in a direction out of the figure.

The first, second, third, and fourth semiconductor devices 1102A, 1102B, 1102C, and 1102D are disposed at 90-degree offsets on the wall of the chamber 1104 having a circular cross section. Each is mounted as described for the semiconductor device 702 of FIG. 7.

A configuration such as shown in FIG. 8 or 11 might be particularly well suited to applications wherein the semiconductor devices are part of a bridge circuit, such that not all of the semiconductor devices are dissipating heat at any particular time.

A person of ordinary skill in the pertinent arts would understand that the distinctive features of FIGS. 7 through 11 may be combined according to the requirements of an application.

Illustrative embodiments have been provided for a semiconductor device having a fin-like configuration and suitable for use with immersion cooling. The embodiments have high power dissipation into the coolant transfer, having leads with low parasitics, and enable a low impedance or controlled-impudence interface between the semiconductor device immersed in a chamber of an immersion cooling system and circuitry outside the chamber.

The technologies shown in the illustrated embodiments may be combined. For example, a plurality of device dies having a high length-to-width aspect ratio may be arranged a one-dimensional rectangular array pattern along the axis corresponding to their width.

Aspects of the present disclosure have been described in conjunction with the specific embodiments that are presented as illustrative examples. Numerous alternatives, modifications, and variations to the disclosed embodiments may be made without departing from the scope of the claims set forth below. Embodiments disclosed herein are not intended to be limiting.

What is claimed is:

1. A semiconductor device comprising:
a first lead comprising a planar stripline;
a second lead comprising a planar stripline;
a first semiconductor die mounted on the first lead and comprising:
a bottom pad disposed on a first side of the first semiconductor die and electrically coupled to the first lead; and
a first top pad disposed on a second side of the first semiconductor die and electrically coupled to the second lead,
wherein a shape of the semiconductor device corresponds to a fin, and
wherein the semiconductor device is configured for immersion cooling.

2. The semiconductor device of claim 1, wherein the first and second leads comprise a low impedance or controlled-impendence interconnect between the first semiconductor die and circuitry external to the semiconductor device.

3. The semiconductor device of claim 1,
wherein the first lead is soldered or brazed to the bottom pad, and
wherein the second lead is soldered or brazed to the first top pad.

4. The semiconductor device of claim 1, further comprising:
a third lead comprising a planar stripline;
wherein the first semiconductor die further comprises a second top pad disposed on the second side of the first semiconductor die;
wherein the second top pad is electrically coupled to the third lead; and
wherein the planar stripline of the third lead is co-planar with the planar stripline of the second lead.

5. The semiconductor device of claim 4, further comprising:
a fourth lead comprising a planar stripline;
wherein the first semiconductor die further comprises a third top pad disposed on the second side of the first semiconductor die;
wherein the third top pad is electrically coupled to the fourth lead; and
wherein the planar stripline of the fourth lead is co-planar with the planar stripline of the third lead and the planar stripline of the second lead.

6. The semiconductor device of claim 1, further comprising an encapsulant disposed over and around the first semiconductor die.

7. The semiconductor device of claim 6, wherein a thickness of the encapsulant over the first semiconductor die is five microns or less.

8. The semiconductor device of claim 6, further comprising the encapsulant disposed around a portion of the first lead and a portion of the second lead.

9. The semiconductor device of claim 6, wherein the encapsulant is electrically non-conductive.

10. The semiconductor device of claim 1, further comprising:
a second semiconductor die mounted on the first lead and comprising:
a bottom pad disposed on a first side of the second semiconductor die and electrically coupled to the first lead; and
a second top pad disposed on a second side of the second semiconductor die and electrically coupled to the second lead.

11. The semiconductor device of claim 1, further comprising:
a third lead comprising a planar stripline; and
a second semiconductor die mounted on the first lead and comprising:
a bottom pad disposed on a first side of the second semiconductor die and electrically coupled to the first lead, and
a second top pad disposed on a second side of the second semiconductor die and electrically coupled to the third lead.

12. The semiconductor device of claim 1,
wherein the first semiconductor die further comprises a second top pad disposed on the second side of the first semiconductor die; and
wherein the second top pad is electrically coupled to the second lead.
